(19) United States
(12) Patent Application Publication
(10) Pub. No.: US 2013/0285471 A1
(43) Pub. Date: Oct. 31, 2013

(54) TUNER CIRCUIT

(71) Applicants: DONG-LIANG REN, Shenzhen City (CN); HSING-SUANG KAO, Tu-Cheng (TW)

(72) Inventors: DONG-LIANG REN, Shenzhen City (CN); HSING-SUANG KAO, Tu-Cheng (TW)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/527,918

(22) Filed: Jun. 20, 2012

(30) Foreign Application Priority Data
Apr. 25, 2012 (CN) 201210124138.3

(51) Int. Cl. H03K 3/00

(52) U.S. Cl. 307/113

(57) ABSTRACT

An exemplary tuner circuit is provided. The circuit includes a power control system, a first switch module, and a second switch module. The first switch module is connected between the power control system and an electronic component. The second switch module is connected between the power control system and a tuner. The power control system is independent of the electronic component it supplies. When the tuner is turned on, the power control system outputs a high level voltage to the first switch module and outputs a low level voltage to the second switch module, the first switch module disconnects power to the electronic component, the second switch module re-establishes a connection between the power control system and the tuner according to the low level voltage output by the power control system.

### BACKGROUND

1. Technical Field

The present disclosure relates to electrical circuits and, more particularly, to a tuner circuit.

2. Description of Related Art

Many electronic devices, such as DVD players, include a tuner to receive external signals. However, when a CPU of the electronic devices is working, the CPU may generate electromagnetic interference that adversely influences the tuner, which may result in a decrease in intensity of the signals collected and forwarded by the tuner. It is therefore desirable to provide a new tuner circuit to resolve the above problem.

### BRIEF DESCRIPTION OF THE DRAWINGS

The components in the drawings are not necessarily drawn to scale, the emphasis instead being placed upon clearly illustrating the principles of the tuner circuit. Moreover, in the drawings, like reference numerals designate corresponding parts throughout the several views.

FIG. 1 is a block diagram of a tuner circuit in accordance with an exemplary embodiment.

FIG. 2 is a circuit diagram of the tuner circuit of FIG. 1, in accordance with an exemplary embodiment.

### DETAILED DESCRIPTION

The disclosure is illustrated by way of example and not by way of limitation in the figures of the accompanying drawings. It should be noted that references to “an” or “one” embodiment in this disclosure are not necessarily to the same embodiment, and such references mean “at least one”.

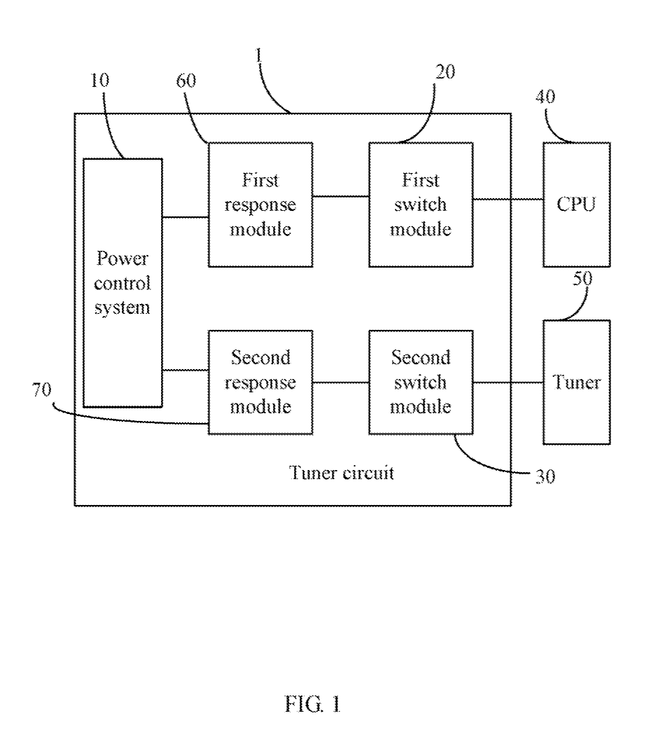

Referring to FIG. 1, a block diagram of a tuner circuit 1 is shown. The tuner circuit 1 includes a power control system 10, a first switch module 20, and a second switch module 30. The first switch module 20 is connected between the power control system 10 and a CPU 40, and is to control a connection between the power control system 10 and the CPU 40. The second switch module 30 is connected between the power control system 10 and a tuner 50, and is to control a connection between the power control system 10 and the tuner 50. The power control system 10 is independent of the CPU 40 for controlling the cut-off and supply of the power, works independently whether the CPU 40 is operating or not. The tuner 50 includes a processor (not shown). When the power of the CPU 40 is cut off, the processor converts content into signals for the tuner 50 to forward, or, converts signals received by the tuner 50 into data and controls a display unit (not shown) to display the data and/or to convert the data such that an audio playing device (not shown) can output sound.

When the tuner 50 is turned on, the power control system 10 outputs a high level voltage to the first switch module 20 and outputs a low level voltage to the second switch module 30. The first switch module 20 disconnects the power to the CPU 40 according to the high level voltage output by the power control system 10. The second switch module 30 re-establishes a connection between the power control system 10 and the tuner 50 according to the low level voltage output by the power control system 10.

When the tuner 50 is turned off, the power control system 10 outputs a low level voltage to the first switch module 20 and outputs a high level voltage to the second switch module 30. The first switch module 20 re-establishes a connection between the power control system 10 and the CPU 40 according to the low level voltage output by the power control system 10. The second switch module 30 disconnects the power to the tuner 50 according to the high level voltage output by the power control system 10.

In the embodiment, the tuner circuit 1 further includes a first response module 60 and a second response module 70. The first response module 60 is connected between the power control system 10 and the first switch module 20, and the second response module 70 is connected between the power control system 10 and the second switch module 30.

When the tuner 50 is turned on to receive signals, the power control system 10 outputs a high level voltage to the first response module 60 and outputs a low level voltage to the second response module 70. The first response module 60 outputs a high level voltage to the first switch module 20, and the first switch module 20 disconnects the power to the CPU 40 according to the high level voltage output by the first response module 60. The second response module 70 outputs a low level voltage to the second switch module 30, and the second switch module 30 re-establishes a connection between the power control system 10 and the tuner 50 according to the low level voltage output by the second switch module 30.

When the tuner 50 is turned off, the power control system 10 outputs a low level voltage to the first response module 60 and outputs a high level voltage to the second response module 70. The first response module 60 outputs a low level voltage to the first switch module 20, and the first switch module 20 re-establishes a connection between the power control system 10 and the CPU 40 according to the low level voltage output by the first response module 60. The second response module 70 outputs a high level voltage to the second switch module 30, and the second switch module 30 disconnects the power to the tuner 50 according to the high level voltage output by the second response module 70.

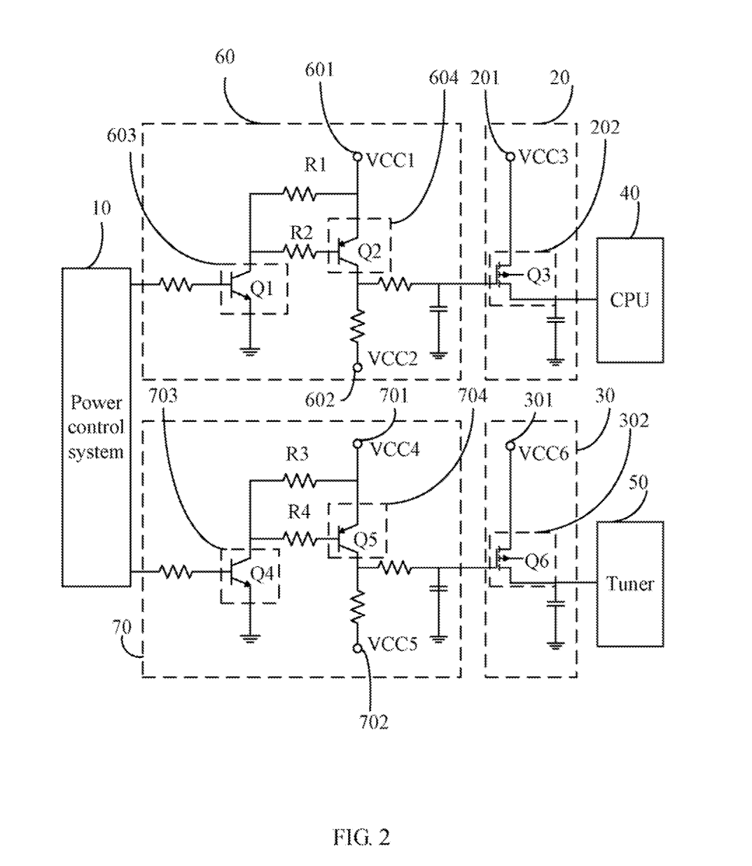

FIG. 2 shows a circuit diagram of the tuner circuit 1 in accordance with an exemplary embodiment.

The first response module 60 includes a first power supply 601, a second power supply 602, a high voltage activated switch 603, and a low voltage activated switch 604. The first power supply 601 is to provide a high level voltage, and the second power supply 602 is to provide a low level voltage. In the embodiment, the high voltage activated switch 603 is an npn bipolar junction transistor (BJT) Q1, the low voltage activated switch 604 is a pnp BJT Q2. The npn BJT Q1 includes a base, an emitter, and a collector. The base of the npn BJT Q1 is connected to the power control system 10, the emitter of the npn BJT Q1 is grounded, and the collector of the npn BJT Q1 is connected to the pnp BJT Q2. The pnp BJT Q2 includes a base, an emitter, and a collector. A resistor R1 and a resistor R2 are connected in series between the emitter of the pnp BJT Q2 and the base of the pnp BJT Q2, and both are connected to the collector of the npn BJT Q1. The emitter of pnp BJT Q2 is connected to the first power supply 601, the collector of the pnp BJT Q2 is connected to the second power supply 602 and the first switch module 20.

The first switch module 20 includes a third power supply 201 and a high voltage activated switch 202. The third power supply 201 is to provide a high level voltage. In the embodiment, the high voltage activated switch 202 is an nmos n-channel metal-oxide-semiconductor field-effect transistor (NMOSFET) Q3. The NMOSFET Q3 includes a gate, a source, and a drain. The gate of the NMOSFET Q3 is connected to the collector of the pnp BJT Q2, the source of the NMOSFET Q3 is connected to the third power supply 201, and the drain of the NMOSFET Q3 is connected to the CPU 40.

The second response module 70 includes a fourth power supply 701, a fifth power supply 702, a high voltage activated switch 703, and a low voltage activated switch 704. The fourth power supply 701 is to provide a high level voltage, and the fifth power supply 702 is to provide a low level voltage. In the embodiment, the high voltage activated switch 703 is an npn bipolar junction transistor (BJT) Q4, the low voltage activated switch 704 is a pnp BJT Q5. The npn BJT Q4 includes a base, an emitter, and a collector. The base of the npn BJT Q4 is connected to the power control system 10, the emitter of the npn BJT Q4 is grounded, and the collector of the npn BJT Q4 is connected to the pnp BJT Q5. The pnp BJT Q5 includes a base, an emitter, and a collector. A resistor R3 and a resistor R4 are connected in series between the emitter of the pnp BJT Q5 and the base of the pnp BJT Q5, and both connected to the collector of the npn BJT Q4. The emitter of pnp BJT Q5 is connected to the fourth power supply 701, the collector of the pnp BJT Q5 is connected to the fifth power supply 702 and the first switch module 20.

The second switch module 30 includes a sixth power supply 301 and a high voltage activated switch 302. The sixth power supply 301 is to provide a high level voltage. In the embodiment, the high voltage activated switch 302 is an nmos n-channel metal-oxide-semiconductor field-effect transistor (NMOSFET) Q6. The NMOSFET Q6 includes a gate, a source, and a drain. The gate of the NMOSFET Q6 is connected to the collector of the pnp BJT Q5, the source of the NMOSFET Q6 is connected to the sixth power supply 301, and the drain of the NMOSFET Q6 is connected to the tuner 50.

When the tuner 50 is turned on, the power control system 10 outputs a high level voltage to the base of the npn BJT Q1, thus the base voltage of the npn BJT Q1 is greater than the emitter voltage of the npn BJT Q1, thereby bringing the npn BJT Q1 into conduction. The base of the pnp BJT Q2 is grounded through the npn BJT Q1. The first power supply 601 is connected to the emitter of the pnp BJT Q2 to provide a high level voltage to the emitter of the pnp BJT Q2, thus the emitter voltage of the pnp BJT Q2 is greater than the base voltage of the pnp BJT Q2, thereby bringing the pnp BJT Q2 into conduction. The first power supply 601 provides a high level voltage to the gate of the NMOSFET Q3 through the pnp BJT Q2, the third power supply 201 provides a high level voltage to the source of the NMOSFET Q3, thus the gate voltage of the NMOSFET Q3 is equal to or greater than the source voltage of the NMOSFET Q3, rendering the NMOSFET Q3 non-conducting, to break the connection between the power control system 10 and the CPU 40.

Simultaneously, the power control system 10 outputs a low level voltage to the base of the npn BJT Q4, thus the base voltage of the npn BJT Q4 is equal to or less than the emitter voltage of the npn BJT Q4, rendering the npn BJT Q4 non-conducting. The fourth power supply 701 is connected to the base of the pnp BJT Q5 through the resistor R3 and the resistor R4 to provide a high level voltage to the base of the pnp BJT Q5. The fourth power supply 701 is connected to the emitter of the pnp BJT Q5 to provide a high level voltage to the emitter of the pnp BJT Q5, thus the emitter voltage of the pnp BJT Q5 is equal to or less than the base voltage of the pnp BJT Q5, rendering the pnp BJT Q5 non-conducting. The fifth power supply 702 provides a low level voltage to the gate of NMOSFET Q6, the sixth power supply 301 provides a high level voltage to the source of the NMOSFET Q6, thus the gate voltage of the NMOSFET Q6 is far less than the source voltage of the NMOSFET Q6, thereby bringing the NMOSFET Q6 into conduction, to make a connection between the power control system 10 and the tuner 50. Since the fifth power supply 702 provides a low level voltage to the gate of the NMOSFET Q6, the difference between the gate voltage of the NMOSFET Q6 and the source voltage of the NMOSFET Q6 is larger. The resistance of the NMOSFET Q6 decreases as the difference between the gate voltage of the NMOSFET Q6 and the source voltage of the NMOSFET Q6 increases, thus the resistance of the NMOSFET Q6 becomes less when the NMOSFET Q6 is conducting, and the voltage consumed by the NMOSFET Q6 decreases, which results in the voltage provided by the power control system 10 being able to satisfy the voltage requirement of the tuner 50.

When the tuner 50 is turned off, the power control system 10 outputs a low level voltage to the base of the npn BJT Q1, thus the base voltage of the npn BJT Q1 is equal to or less than the emitter voltage of the npn BJT Q1, rendering the npn BJT Q1 non-conducting. The first power supply 601 is connected to the base of the pnp BJT Q2 through the resistor R1 and the resistor R2 to provide a high level voltage to the base of the pnp BJT Q2. The first power supply 601 is connected to the emitter of the pnp BJT Q2 to provide a high level voltage to the emitter of the pnp BJT Q2, thus the emitter voltage of the pnp BJT Q2 is equal to or less than the base voltage of the pnp BJT Q2, rendering the pnp BJT Q2 non-conducting. The second power supply 602 provides a low level voltage to the gate of NMOSFET Q3, the third power supply 201 provides a high level voltage to the source of the NMOSFET Q3, thus the gate voltage of the NMOSFET Q3 is far less than the source voltage of the NMOSFET Q3, thereby bringing the NMOSFET Q3 into conduction, to make a connection between the power control system 10 and the CPU 40. Since the second power supply 602 provides a low level voltage to the gate of the NMOSFET Q3, the difference between the gate voltage of the NMOSFET Q3 and the source voltage of the NMOSFET Q3 is larger. The resistance of the NMOSFET Q3 decreases as the difference between the gate voltage of the NMOSFET Q3 and the source voltage of the NMOSFET Q3 increases, thus the resistance of the NMOSFET Q3 becomes less, and the voltage consumed by the NMOSFET Q3 decreases, which results in the voltage provided by the power control system 10 being able to satisfy the voltage requirement of the CPU 40.

Simultaneously, the power control system 10 outputs a high level voltage to the base of the npn BJT Q4, thus the base voltage of the npn BJT Q4 is greater than the emitter voltage of the npn BJT Q4, thereby bringing the npn BJT Q4 into conduction. The base of the pnp BJT Q5 is grounded through the npn BJT Q4. The fourth power supply 701 is connected to the emitter of the pnp BJT Q5 to provide a high level voltage to the emitter of the pnp BJT Q5, thus the emitter voltage of the pnp BJT Q5 is greater than the base voltage of the pnp BJT Q5, thereby bringing the pnp BJT Q5 into conduction. The fourth power supply 701 provides a high level voltage to the gate of the NMOSFET Q6 through the pnp BJT Q5, the sixth power supply 301 provides a high level voltage to the source of the NMOSFET Q6, thus the gate voltage of the NMOSFET Q6 is equal to or greater than the source voltage of the NMOSFET Q6, which renders the NMOSFET Q6 non-conducting, thereby breaking the connection between the power control system 10 and the tuner 50.

In the configuration, when the tuner 50 is turned on, the power control system 10 supplies power to the tuner 50 and cuts off the power of the CPU 40, namely, when the tuner 50 is working, the CPU 40 is turned off, which removes from the tuner 50 any electromagnetic interface generated by the CPU 40. The application of this circuit is not limited to cutting off the power to the CPU 40 only, but also can cut off the power to other electronic components, such as an optical disc drive.

Although the current disclosure has been specifically described on the basis of the exemplary embodiment thereof, the disclosure is not to be construed as being limited thereto. Various changes or modifications may be made to the embodiment without departing from the scope and spirit of the disclosure.

What is claimed is:

1. A tuner circuit comprising:
a power control system;
a first switch module connected between the power control system and an electronic component, to control a connection between the power control system and the electronic component; and
a second switch module connected between the power control system and a tuner, and to control a connection between the power control system and the tuner;
wherein the power control system is independent of the electronic component, when the tuner is turned on, the power control system outputs a high level voltage to the first switch module and outputs a low level voltage to the second switch module, the first switch module disconnects the power to the electronic component according to the high level voltage output by the power control system, the second switch module re-establishes a connection between the power control system and the tuner according to the low level voltage output by the power control system.

2. The tuner circuit as described in claim 1, wherein when the tuner is turned off, the power control system outputs a low level voltage to the first switch module and outputs a high level voltage to the second switch module, the first switch module re-establishes a connection between the power control system and the electronic component according to the low level voltage output by the power control system, the second switch module disconnects the power to the tuner according to the high level voltage output by the power control system.

3. The tuner circuit as described in claim 1, further comprising:
a first response module connected between the power control system and the first switch module; and
a second response module connected between the power control system and the second switch module;
wherein when the tuner is turned on, the power control system outputs a high level voltage to the first response module and outputs a low level voltage to the second response module, the first response module outputs a high level voltage to the first switch module according to the high level voltage output by the power control system, the first switch module disconnects the power to the electronic component according to the high level voltage output by the first switch module, the second response module outputs a low level voltage to the second switch module according to the low level voltage output by the power control system, the second switch module re-establishes a connection between the power control system and the tuner according to the low level voltage output by the second switch module.

4. The tuner circuit as described in claim 3, wherein when the tuner is turned off, the power control system outputs a low level voltage to the first response module and outputs a high level voltage to the second response module, the first response module outputs a low level voltage to the first switch module according to the low level voltage output by the power control system, the first switch module re-establishes a connection between the power control system and the electronic component according to the low level voltage output by the first switch module, the second response module outputs a high level voltage to the second switch module according to the high level voltage output by the power control system, the second switch module disconnects the power to the tuner according to the high level voltage output by the second switch module.

5. The tuner circuit as described in claim 4, wherein the first response module comprises a first power supply, a second power supply, a high voltage activated switch, and a low voltage activated switch, the first power supply is to provide a high level voltage, the second power supply is to provide a low level voltage, a first terminal of the high voltage activated switch is connected to the power control system, a second terminal of the high voltage activated switch is grounded, and a third terminal of the high voltage activated switch is connected to the low voltage activated switch, a first resistor and a second resistor are connected in series between a first terminal of the low voltage activated switch and a second terminal of the low voltage activated switch, and are both connected to the high voltage activated switch, the second terminal of the low voltage activated switch is connected to the first power supply, a third terminal of the low voltage activated switch is connected to the second power supply and the first switch module.

6. The tuner circuit as described in claim 5, wherein the high voltage activated switch is an npn bipolar junction transistor (BJT) and the low voltage activated switch is a pnp BJT.

7. The tuner circuit as described in claim 6, wherein the npn BJT comprises a base, an emitter, and a collector, the base of the npn BJT is connected to the power control system, the emitter of the npn BJT is grounded, and the collector of the npn BJT is connected to the pnp BJT, the first resistor and the second resistor are connected in series between the base of the pnp BJT and the emitter of the pnp BJT, and both connected to the collector of the npn BJT, the emitter of the pnp BJT is connected to the first power supply, the collector of the pnp BJT is connected to the second power supply and the first switch module.

8. The tuner circuit as described in claim 4, wherein the first switch module comprises a third power supply and a high voltage activated switch, a third power supply is to provide a high level voltage, a first terminal of the high voltage activated switch is connected to the first response module, a second terminal of the high voltage activated switch is connected to the third power supply, and the third terminal of the high voltage activated switch is connected to the electronic component.

9. The tuner circuit as described in claim 8, wherein the high voltage activated switch is an nmos n-channel metal-oxide-semiconductor field-effect transistor (NMOSFET).

10. The tuner circuit as described in claim 9, wherein the NMOSFET comprises a gate, a source, and a drain, the gate of the NMOSFET is connected to the first response module, the source of the NMOSFET is connected to the third power supply, and the drain of the NMOSFET is connected to the electronic component.

11. The tuner circuit as described in claim 4, wherein the second response module comprises a fourth power supply, a fifth power supply, a high voltage activated switch, and a low voltage activated switch, the fourth power supply is to provide a high level voltage, the fifth power supply is to provide a low level voltage, a first terminal of the high voltage activated switch is connected to the power control system, a second terminal of the high voltage activated switch is grounded, and a third terminal of the high voltage activated switch is connected to the low voltage activated switch, a third resistor and a fourth resistor are connected in series between a first terminal of the low voltage activated switch and a second terminal of the low voltage activated switch, and are both connected to the high voltage activated switch, the second terminal of the low voltage activated switch is connected to the fourth power supply, a third terminal of the low voltage activated switch is connected to the fifth power supply and the first switch module.

12. The tuner circuit as described in claim 11, wherein the high voltage activated switch is an npn bipolar junction transistor (BJT) and the low voltage activated switch is a pnp BJT.

13. The tuner circuit as described in claim 11, wherein the npn BJT comprises a base, an emitter, and a collector, the base of the npn BJT is connected to the power control system, the emitter of the npn BJT is grounded, the collector of the npn BJT is connected to the pnp BJT, the pnp BJT comprises a base, an emitter, and a collector, a third resistor and a fourth resistor are connected in series between the base of the pnp BJT and the emitter of the pnp BJT, and both connected to the collector of the npn BJT, the emitter of the pnp BJT is connected to the fourth power supply, the collector of the pnp BJT is connected to the fifth power supply and the first switch module.

14. The tuner circuit as described in claim 4, wherein the second switch module comprises a sixth power supply and a high voltage activated switch, a sixth power supply is to provide high level voltage, a first terminal of the high voltage activated switch is connected to the second response module, a second terminal of the high voltage activated switch is connected to the sixth power supply, and a third terminal of the high voltage activated switch is connected to the tuner.

15. The tuner circuit as described in claim 14, wherein the high voltage activated switch is an nmos n-channel metal-oxide-semiconductor field-effect transistor (NMOSFET).

16. The tuner circuit as described in claim 15, wherein the NMOSFET comprises a gate, a source, and a drain, the gate of the NMOSFET is connected to the second response module, the source of the NMOSFET is connected to the sixth power supply, and the drain of the NMOSFET is connected to the tuner.

17. The tuner circuit as described in claim 1, wherein the electronic component is a center processing unit (CPU).
